(19) United States
(12) Patent Application Publication
(10) Pub. No.: US 2026/0223492 A1
(43) Pub. Date: Jul. 30, 2026

(54) LIGHT-EMITTING SEMICONDUCTOR ELEMENT AND LIGHT-EMITTING SEMICONDUCTOR DEVICE

(71) Applicant: STANLEY ELECTRIC CO., LTD., Tokyo (JP)

(72) Inventors: Katsuya NAKADA, Tokyo (JP); Yasuyuki SHIBATA, Tokyo (JP); Akio OGAWA, Tokyo (JP)

(73) Assignee: STANLEY ELECTRIC CO., LTD., Tokyo (JP)

(21) Appl. No.: 19/147,719

(22) PCT Filed: Dec. 21, 2023
(86) PCT No.: PCT/JP2023/045880

§ 371 Date: Jul. 14, 2025

(30) Foreign Application Priority Data
Jan. 23, 2023 (JP) 2023-008044

(51) Int. Cl. H10H 20/831; H10H 20/01; H10H 20/819; H10H 20/84; H10H 20/85; H10H 20/857

(52) U.S. Cl. CPC H10H 20/831; H10H 20/032; H10H 20/0364; H10H 20/819; H10H 20/84; H10H 20/8508; H10H 20/857

(57) ABSTRACT

A semiconductor light-emitting element includes: light-emitting functional semiconductor layer provided on light-transmitting substrate including light-emitting functional portion of stacked semiconductor layer of first semiconductor layer, light-emitting layer, and second semiconductor layer sequentially stacked and separated by separation groove; first electrode on bottom surface of the separation groove; second electrode on the second semiconductor layer; first insulating film; connection pad electrode connected to the second electrode through an opening; annular recess entirely surrounding the light-emitting functional portion and the first electrode; and annular sealing electrode wall in non-conductive contact with the first semiconductor layer exposed from bottom surface of the annular recess and erected in annular shape on the first semiconductor layer, and entirely surrounds the light-emitting functional portion and the first electrode. The annular sealing electrode wall is in direct contact with one end of the first electrode and electrically connected to the first electrode.

### TECHNICAL FIELD

The present invention relates to a semiconductor light-emitting element and a semiconductor light-emitting device, and more particularly to a semiconductor light-emitting element such as a light-emitting diode (LED) and a semiconductor light-emitting device including the semiconductor light-emitting element.

### BACKGROUND ART

In recent years, semiconductor light-emitting elements such as light-emitting diodes (LEDs) and laser diodes (LDs) have come into widespread use, and research and development into achieving higher output and shorter wavelengths has been actively carried out. In particular, there is an increasing demand for higher output and longer life for ultraviolet semiconductor light-emitting elements, for example, semiconductor light-emitting elements that emit deep ultraviolet light having a high sterilizing ability.

For example, Patent Literature 1 discloses an optical semiconductor device including an optical semiconductor element, a mounting substrate on which the optical semiconductor element is mounted, and a sealing portion that seals a space between a seal ring and the mounting substrate, in which the number of parts required for sealing is reduced to lower manufacturing costs while maintaining the reliability of the sealing.

Furthermore, Patent Literature 2 discloses a semiconductor device in which, when a semiconductor element is mounted on a support substrate, a portion of a connection member melts and the molten metal remains within an opening formed in a dam film, thereby preventing the occurrence of a short circuit between electrodes.

Furthermore, Patent Literature 3 discloses a semiconductor light-emitting device in which a plurality of mesa-shaped active regions surrounded by cutout regions are formed in a light-emitting region, one electrode is formed in the cutout region surrounding each mesa-shaped active region, and the other electrode is formed on each mesa-shaped active region, thereby enabling current to be efficiently supplied with low resistance to any position in the light-emitting region.

However, there is a problem in that semiconductor light-emitting elements, particularly short wavelength light-emitting elements such as deep ultraviolet semiconductor light-emitting elements, are easily deteriorated in environments of high temperature, high humidity, and the like. In particular, in AlGaN-based light-emitting elements, in a case where an emission wavelength is a short wavelength of less than 360 nm (corresponding to the band gap of 3.4 eV of GaN), there has been a problem in that the environmental resistance of the p-type semiconductor layer to high temperatures, high humidity, and the like decreases when an electrical current flows.

### CITATION LIST

### Patent Literatures

Patent Literature 1: Japanese Patent Application Laid-Open No. 2018-93136
Patent Literature 2: Japanese Patent Application Laid-Open No. 2005-150386
Patent Literature 3: Japanese Patent Application Laid-Open No. 2005-322847

### SUMMARY OF INVENTION

### Technical Problem

The present invention has been made in view of the above-described points, and an object of the present invention is to provide a semiconductor light-emitting element and a semiconductor light-emitting device that are highly reliable even in harsh environments such as high temperature, high humidity, and corrosive gas environments.

### Solution to Problem

According to an embodiment of the present invention, there is provided a semiconductor light-emitting element including:
a light-transmitting element substrate;
a light-emitting functional semiconductor layer that is provided on the element substrate and includes at least one light-emitting functional portion, each of which consists of a stacked semiconductor layer in which a first semiconductor layer, a light-emitting layer, and a second semiconductor layer are sequentially stacked, and which is separated by a separation groove having a bottom surface where the first semiconductor layer is exposed;
at least one first electrode provided on the bottom surface of the separation groove;
a second electrode provided on the second semiconductor layer of the light-emitting functional portion;
a first insulating film that covers the at least one light-emitting functional portion, the separation groove, the first electrode, and the second electrode, and has an opening where a portion of the second electrode is exposed;
a connection pad electrode that is electrically connected to the second electrode through the opening and entirely covers the at least one light-emitting functional portion and the separation groove;
an annular recess that entirely surrounds the at least one light-emitting functional portion and the at least one first electrode and has a bottom surface where the first semiconductor layer is exposed; and
an annular sealing electrode wall that is in non-conductive contact with the first semiconductor layer exposed from the bottom surface of the annular recess and is erected in an annular shape on the exposed first semiconductor layer, and that entirely surrounds the at least one light-emitting functional portion and the first electrode, in which
the annular sealing electrode wall is in direct contact with one end of the first electrode and electrically connected to the first electrode.

According to another embodiment of the present invention, there is provided a semiconductor light-emitting device including:
the semiconductor light-emitting element; and
a wiring substrate including a sealing placing wiring having an annular shape corresponding to the sealing electrode wall of the semiconductor light-emitting element, the sealing electrode wall and the sealing placing wiring being airtightly bonded by a bonding member.

### BRIEF DESCRIPTION OF DRAWINGS

FIG. 1A is a top view schematically illustrating a semiconductor light-emitting device according to a first embodiment of the present invention as viewed from the top side (light-emitting surface side).

FIG. 1B is a view schematically illustrating a side surface of the semiconductor light-emitting device as viewed from a direction V illustrated in FIG. 1A.

FIG. 1C is a view schematically illustrating a back surface of the semiconductor light-emitting device.

FIG. 2 is a cross-sectional view schematically illustrating a cross section of the semiconductor light-emitting device taken along line A-A illustrated in FIG. 1A.

FIG. 3A is a view schematically illustrating an element upper surface of the semiconductor light-emitting element as viewed from a bonding surface side of a semiconductor light-emitting element 10A and a wiring substrate 40.

FIG. 3B is a cross-sectional view illustrating a cross section of the semiconductor light-emitting element taken along a center line CX illustrated in FIG. 3A.

FIG. 3C is a cross-sectional view illustrating a cross section of the semiconductor light-emitting element taken along line C-C illustrated in FIG. 3A.

FIG. 3D is a cross-sectional view illustrating a cross section of the semiconductor light-emitting element taken along line D-D illustrated in FIG. 3A.

FIG. 4A is a view schematically illustrating an upper surface of a wiring substrate as viewed from the bonding surface side.

FIG. 4B is a cross-sectional view illustrating a cross section of the wiring substrate taken along a center line CX illustrated in FIG. 4A.

FIG. 5A is a cross-sectional view illustrating steps S0 to S3 of a manufacturing method for a semiconductor light-emitting device according to a first embodiment.

FIG. 5B is a cross-sectional view illustrating steps S4 to S7 of the manufacturing method for a semiconductor light-emitting device according to the first embodiment.

FIG. 5C is a cross-sectional view illustrating steps S8 to S9 of the manufacturing method for a semiconductor light-emitting device according to the first embodiment.

FIG. 5D is a cross-sectional view illustrating step S10 of the manufacturing method for a semiconductor light-emitting device according to the first embodiment.

FIG. 6 is a graph showing results of a moisture resistance test of a semiconductor light-emitting device according to Example 1 (EMB1).

FIG. 7A is a top view schematically illustrating a semiconductor light-emitting device according to Comparative Example 1 (CMP1) as viewed from above (the light-emitting surface side).

FIG. 7B is a view schematically illustrating a side surface of the semiconductor light-emitting device according to Comparative Example 1 as viewed from a direction V illustrated in FIG. 7A.

FIG. 7C is a graph showing results of a moisture resistance test of the semiconductor light-emitting device according to Comparative Example 1.

FIG. 8A is a view schematically illustrating an element upper surface of a semiconductor light-emitting element according to Modification Example 1 of the first embodiment.

FIG. 8B is a cross-sectional view illustrating a cross section taken along a center line CX of a semiconductor light-emitting device according to Modification Example 1 formed by bonding the semiconductor light-emitting element according to Modification Example 1 to a wiring substrate.

FIG. 9 is a cross-sectional view illustrating steps S8-2 and S8-3.

FIG. 10A is a cross-sectional view illustrating a bonding preparation step (S10-2) in a modification example (Modification Example 2) of the manufacturing method according to the first embodiment.

FIG. 10B is a cross-sectional view illustrating a pad electrode bonding step (S11-2) in Modification Example 2.

FIG. 10C is a cross-sectional view illustrating a sealing electrode wall bonding step (S11-3) in Modification Example 2.

FIG. 11A is a top view schematically illustrating a semiconductor light-emitting device according to a second embodiment as viewed from the light-emitting surface side.

FIG. 11B is a view schematically illustrating a side surface of the semiconductor light-emitting device as viewed from a direction V illustrated in FIG. 11A.

FIG. 11C is a cross-sectional view schematically illustrating a cross section taken along line A-A illustrated in FIG. 11A.

FIG. 12A is a view schematically illustrating an element upper surface of the semiconductor light-emitting element as viewed from the bonding surface side.

FIG. 12B is a cross-sectional view illustrating a cross section of a semiconductor light-emitting element 60A taken along a center line CX illustrated in FIG. 12A.

FIG. 12C is a cross-sectional view illustrating a cross section taken along line C-C illustrated in FIG. 12A.

FIG. 12D is a cross-sectional view illustrating a cross section taken along line D-D illustrated in FIG. 12A.

FIG. 13A is a top view schematically illustrating a semiconductor light-emitting device according to a third embodiment as viewed from the light-emitting surface side.

FIG. 13B is a view schematically illustrating a side surface of a semiconductor light-emitting device 10 as viewed from a direction V illustrated in FIG. 13A.

FIG. 13C is a cross-sectional view schematically illustrating a cross section taken along line A-A illustrated in FIG. 13A.

FIG. 14A is a top view schematically illustrating a bonding surface (element mounting surface) of a wiring substrate in a semiconductor light-emitting device according to a fourth embodiment.

FIG. 14B is a view schematically illustrating an upper surface of a semiconductor light-emitting device in which a semiconductor light-emitting element and a protective element are mounted.

FIG. 15A is a top view of the semiconductor light-emitting device according to the fourth embodiment.

FIG. 15B is a side view of the semiconductor light-emitting device according to the fourth embodiment.

### DESCRIPTION OF EMBODIMENTS

Hereinafter, preferred embodiments of the present invention will be described, but these embodiments may be appropriately modified and combined. In addition, in the following description and the accompanying drawings, substantially the same or equivalent parts will be described with the same reference numerals.

### First Embodiment

### (1) Structure of Semiconductor Light-Emitting Device

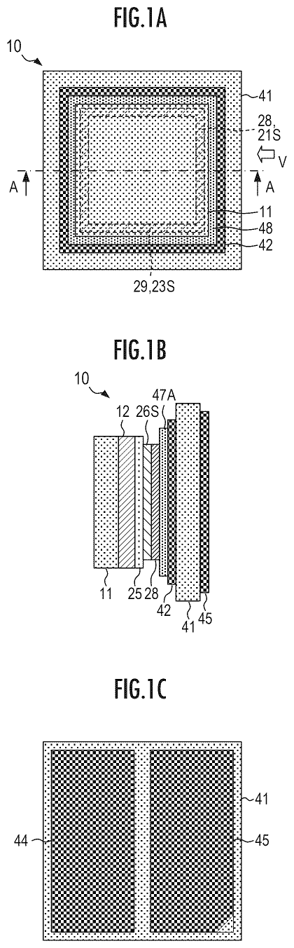

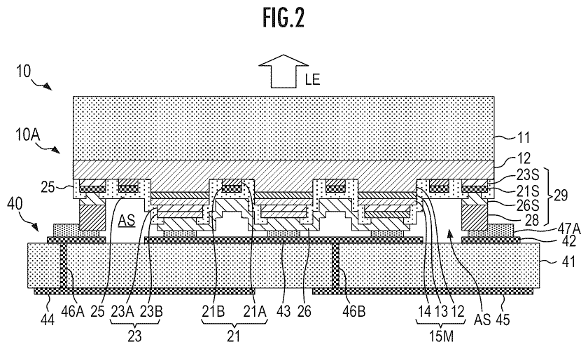

FIG. 1A is a top view schematically illustrating a semiconductor light-emitting device 10 according to a first embodiment of the present invention as viewed from above (a light-emitting surface side) (also referred to as a top view). FIG. 1B is a view schematically illustrating a side surface of the semiconductor light-emitting device 10 as viewed from a direction V illustrated in FIG. 1A. In addition, FIG. 1C is a view schematically illustrating a back surface of the semiconductor light-emitting device 10.

In addition, FIG. 2 is a cross-sectional view schematically illustrating a cross section of the semiconductor light-emitting device 10 taken along line A-A illustrated in FIG. 1A. The structure of the semiconductor light-emitting element 10A will be described in detail below.

As illustrated in FIGS. 1A to 1C and 2, the semiconductor light-emitting device 10 includes a rectangular plate-shaped wiring substrate 40 and a semiconductor light-emitting element 10A bonded to the wiring substrate 40. The semiconductor light-emitting element 10A has a rectangular plate shape, and is provided with a light-transmitting element substrate 11 on one main surface side and a semiconductor light-emitting functional portion 15M on the other main surface side. Light emitted from a semiconductor light-emitting structure layer 12 passes through the element substrate 11 and is emitted from the back surface of the element substrate 11 (emitted light LE).

More specifically, the semiconductor light-emitting element 10A is bonded to the wiring substrate 40 by a bonding member, and is airtightly bonded over the entire periphery of the semiconductor light-emitting element 10A. Further, the light-emitting functional portion 15M is provided with an element electrode, which is electrically connected to the wiring of the wiring substrate 40.

Hereinafter, the semiconductor light-emitting device 10 will be described in more detail with reference to FIGS. 1A to 1C and 2.

### (Semiconductor Light-Emitting Element)

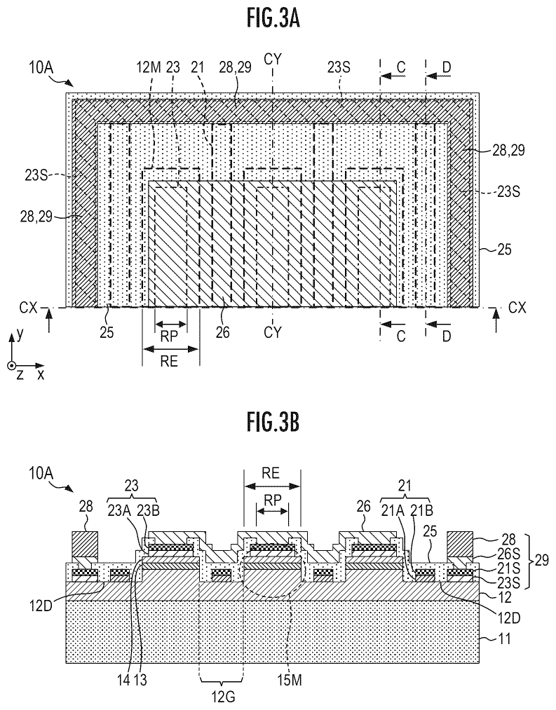

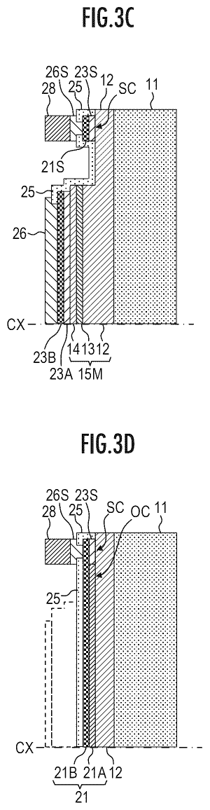

FIG. 3A is a view schematically illustrating an element upper surface of the semiconductor light-emitting element 10A as viewed from a bonding surface side of the semiconductor light-emitting element 10A and the wiring substrate 40. Note that FIG. 3A illustrates the semiconductor light-emitting element 10A in FIG. 2 upside down. Also, the semiconductor light-emitting element 10A has a rectangular structure that is symmetrical with respect to a center line CX, and FIG. 3A illustrates the upper half of the semiconductor light-emitting element 10A above the center line CX.

In addition, FIG. 3B is a cross-sectional view illustrating a cross section of the semiconductor light-emitting element 10A taken along the center line CX illustrated in FIG. 3A. FIGS. 3C and 3D are cross-sectional views illustrating cross sections of the semiconductor light-emitting element 10A taken along lines C-C and D-D illustrated in FIG. 3A, respectively.

As illustrated in FIGS. 3A and 3B, the semiconductor light-emitting element 10A has a rectangular plate shape having four mutually perpendicular side surfaces (side surfaces along the x direction and the y direction). The semiconductor light-emitting element 10A also includes a plurality of light-emitting functional portions 15M, which are light-emitting regions separated from each other by separation grooves 12G. Specifically, each of the plurality of light-emitting functional portions 15M has a mesa shape. In the following, a case where a plurality of light-emitting functional portions 15M are provided will be described, but it is sufficient that at least one light-emitting functional portion 15M is provided.

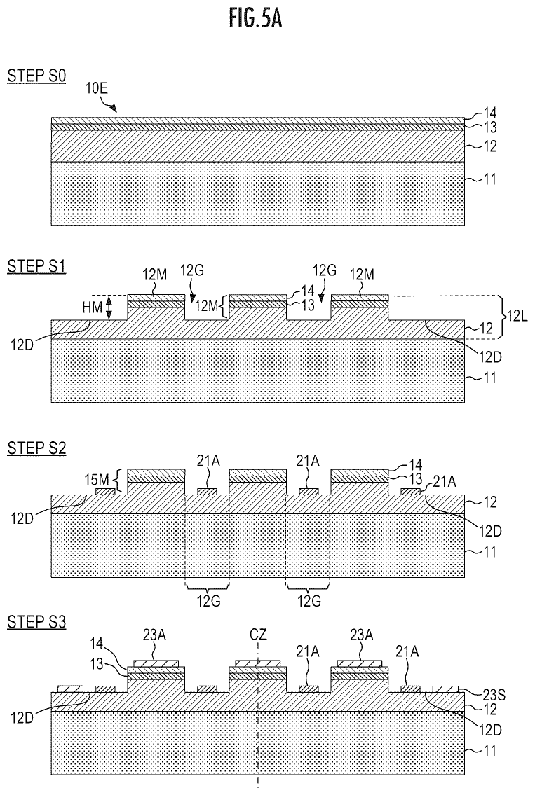

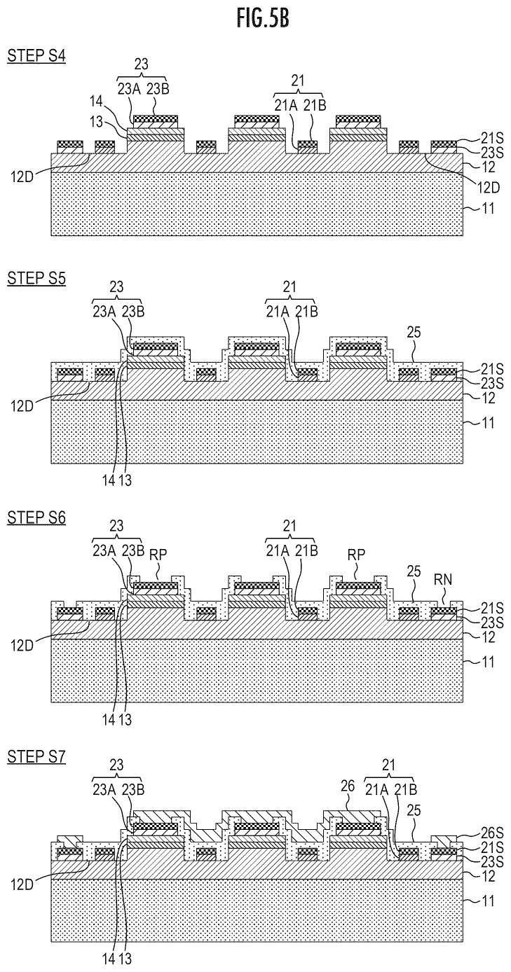

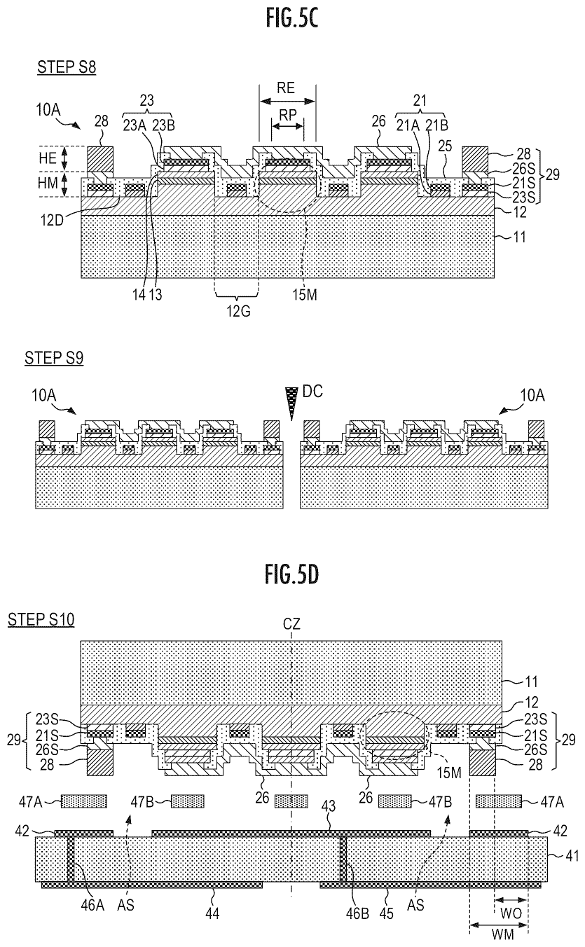

In the present specification, the entire semiconductor layer consisting of the semiconductor layers of the plurality of light-emitting functional portions 15M and the separation grooves 12G is referred to as a light-emitting functional semiconductor layer 12L (see FIG. 5A). The plurality of light-emitting functional portions 15M extend in a direction (y direction) orthogonal to a pair of opposing sides of the light-emitting functional semiconductor layer 12L. In other words, the plurality of light-emitting functional portions 15M extend parallel to the pair of sides.

As illustrated in FIG. 3B, the semiconductor light-emitting element 10A includes a light-transmitting element substrate 11. As the element substrate 11, a substrate such as aluminum nitride (AlN), sapphire, or the like can be used.

The mesa-shaped light-emitting functional portion 15M is made of an aluminum gallium nitride (AlGaN) based semiconductor layer, and can be formed by, for example, a metal organic chemical vapor deposition method (MOCVD method). Note that the crystal growth method is not limited to the MOCVD method, but a molecular beam epitaxy method (MBE method) or the like can be used.

The light-emitting functional portion 15M is formed by growing an n-type semiconductor layer 12 (first semiconductor layer), a light-emitting layer 13, and a p-type semiconductor layer 14 (second semiconductor layer) on the element substrate 11 in that order. The n-type semiconductor layer 12 is, for example, an AlGaN layer doped with silicon (Si).

The light-emitting layer 13 has, for example, a multiple quantum well (MQW) structure in which an AlGaN layer serves as a barrier layer and an AlGaN layer having a smaller band gap than the barrier layer serves as a well layer. The light-emitting layer 13 emits deep ultraviolet light of, for example, 265 nm, but the emission wavelength is not limited thereto.

The p-type semiconductor layer 14 consists of, for example, an AlGaN layer doped with magnesium (Mg) and a contact layer doped with Mg on the AlGaN layer.

Note that the n-type semiconductor layer 12 (first semiconductor layer) and the p-type semiconductor layer 14 (second semiconductor layer) of the light-emitting functional portion 15M are not limited to the above-described compositions. Further, each of the n-type semiconductor layer 12 and the p-type semiconductor layer 14 may be composed of a plurality of layers rather than a single layer, and may also include an undoped layer (i layer).

As illustrated in FIG. 3B, the n-type semiconductor layer 12 is exposed at the bottom surface of the separation groove 12G between the light-emitting functional portions 15M. An n-ohmic electrode 21A is formed on the n-type semiconductor layer 12 exposed at the bottom surfaces of the plurality of separation grooves 12G.

Further, an n-auxiliary electrode 21B is formed on the n-ohmic electrode 21A along the n-ohmic electrode 21A, and the n-ohmic electrode 21A and the n-auxiliary electrode 21B form an n-electrode 21 (first electrode).

As illustrated in FIG. 3A, the plurality of n-electrodes 21 extend along the light-emitting functional portion 15M and are formed in strips parallel to the light-emitting functional portion 15M.

More specifically, the n-ohmic electrode 21A is formed as an ohmic electrode in which titanium (Ti) and aluminum (Al) are formed in that order on the n-type semiconductor layer 12. Note that the n-type semiconductor layer 12 is not limited to a Ti/Al layer, and may be formed of a material for forming ohmic contact with Ti/Rh, Ti/Au, or the like.

The n-auxiliary electrode 21B on the n-ohmic electrode 21A is formed as a Ti/Ni/Au electrode in which Ti, Ni, and Au are formed in that order.

A p-ohmic electrode 23A is formed on the p-type semiconductor layer 14 on the mesa of the light-emitting functional portion 15M, and a p-auxiliary electrode 23B is formed on the p-ohmic electrode 23A. The p-ohmic electrode 23A and the p-auxiliary electrode 23B form a p-electrode 23 (second electrode).

As illustrated in FIG. 3A, the p-electrode 23 extends along the light-emitting functional portion 15M at the top of the light-emitting functional portion 15M, and the plurality of p-electrodes 23 are formed in strips parallel to the light-emitting functional portion 15M. That is, the p-electrode 23 forms a p-connection region RP.

Further, a light-emitting region RE is defined by a mesa-shaped light-emitting functional portion 15M. The light emitted from the light-emitting functional portion 15M in the direction of the p-electrode 23 and the light emitted from the side of the light-emitting functional portion 15M are reflected by the p-electrode 23 and are emitted in the direction of the element substrate 11.

More specifically, the p-ohmic electrode 23A is formed as a Ni/Au electrode in which nickel (Ni) and Au are formed in that order on the p-type semiconductor layer 14. Note that the material of the p-ohmic electrode 23A is not limited to Ni/Au, but may be Ni/platinum (Pt)/Au, Ni/palladium (Pd)/Au, or the like, and is formed of a material that forms ohmic contact with the p-type semiconductor layer 14 but is in Schottky contact with the n-type semiconductor layer 12. Furthermore, a metal having a high reflectance with respect to the light emitted from the light-emitting layer 13 is preferable.

The p-auxiliary electrode 23B on the p-ohmic electrode 23A is formed as a Ti/Ni/Au electrode in which Ti, Ni, and Au are formed in that order.

Note that the p-ohmic electrode 23A may be made of a transparent conductor, and a layer including a light-reflecting layer may be provided thereon. Specifically, in a case where the emission wavelength is a long wavelength of 380 nm or more, an indium tin oxide (ITO) film may be used as the p-ohmic electrode 23A, and Ni/Ag/Ti/Ni/Au layers may be provided as the reflective layer and protective layer.

The side walls and the upper surfaces of the mesa-shaped light-emitting functional portion 15M and the p-electrode 23 are covered with a first insulating film 25 made of SiO₂, thereby providing insulation and protection. On the first insulating film 25, a p-pad electrode (second pad electrode) 26 is formed.

The p-pad electrode 26 is electrically connected to the p-electrode 23 (that is, the p-auxiliary electrode 23B and the p-ohmic electrode 23A) through an opening portion in the first insulating film 25. In other words, the p-electrode 23 is a connection pad electrode electrically connected to the ohmic electrode.

Further, the p-pad electrode 26 covers the upper surface and the side walls of the mesa-shaped light-emitting functional portion 15M via the first insulating film 25, and is formed so as to cover the entire light-emitting region consisting of the plurality of light-emitting functional portions 15M.

Specifically, the p-pad electrode 26 is formed as a Ti/Ni/Au electrode in which Ti, Ni, and Au are formed in that order, but is not limited thereto. It is sufficient that any electrode layer having high adhesion to the n-electrode 21 and high conductivity is used, and the electrode layer may include a barrier metal layer or the like. For example, Ti/Al/Ti-(tungsten) W/Au, Ti/Al/Rh/Au, and the like can be used.

As illustrated in FIG. 3B, an annular recess 12D is provided at the peripheral edge portion of the n-type semiconductor layer 12 so as to be recessed from the upper surface of the n-type semiconductor layer 12 of the light-emitting functional portion 15M. The annular recess 12D is provided so as to entirely surround the plurality of light-emitting functional portions 15M and the plurality of n-electrodes 21. Further, in the present embodiment, the depth of the annular recess 12D is the same as the depth of the separation groove 12G. In other words, the bottom surface of the annular recess 12D and the bottom surface of the separation groove 12G form a continuous flat surface.

On the bottom surface of the annular recess 12D of the n-type semiconductor layer 12, a Schottky metal layer (hereinafter referred to as a Schottky layer 23S) made of the same metal layer as the p-ohmic electrode 23A is formed. The Schottky layer 23S forms a Schottky contact (SC) with the n-type semiconductor layer 12, which forms a non-conductive contact. Accordingly, no current flows between the n-type semiconductor layer 12 and the Schottky layer 23S.

An annular auxiliary electrode 21S made of the same metal layer as the n-auxiliary electrode 21B is formed on the Schottky layer 23S. In addition, an annular pad metal layer 26S made of the same metal layer as the p-pad electrode 26 is formed on the auxiliary electrode 21S. An annular n-pad electrode (first pad electrode) 28 is formed on the pad metal layer 26S.

The n-pad electrode 28, the auxiliary electrode 21S, the pad metal layer 26S, and the Schottky layer 23S are formed in an annular shape (rectangular annular shape) in close contact with each other. That is, the annular Schottky layer 23S is formed along the peripheral edge portion of the n-type semiconductor layer 12 that is perpendicular to and parallel to the light-emitting functional portion 15M.

In addition, as illustrated in FIG. 3A, the n-pad electrode 28, the auxiliary electrode 21S, the pad metal layer 26S, and the Schottky layer 23S are provided on the peripheral edge portion of the n-type semiconductor layer 12, and entirely surround the plurality of light-emitting functional portions 15M and the plurality of n-electrodes 21, and are formed as an airtight annular electrode layer.

That is, the n-pad electrode 28, the auxiliary electrode 21S, the pad metal layer 26S, and the Schottky layer 23S function as an annular sealing electrode wall 29 as a whole. Here, the n-pad electrode 28 functions as a sealing pad electrode. Furthermore, the sealing electrode wall 29 is electrically connected to the plurality of n-electrodes 21, but is insulated from the n-type semiconductor layer 12.

More specifically, as illustrated in FIG. 3C (cross section taken along line C-C in FIG. 3A), in the region where the n-electrode 21 is not formed, the Schottky layer 23S (that is, the sealing electrode wall 29) is not electrically connected (non-conductive) to the n-electrode 21 and is electrically isolated from the n-type semiconductor layer 12.

On the other hand, as illustrated in FIG. 3D (cross section taken along line D-D in FIG. 3A), the Schottky layer 23S (that is, the sealing electrode wall 29) is electrically connected to the n-electrode 21 which is in ohmic contact (OC) with the n-type semiconductor layer 12. More specifically, the Schottky layer 23S is in direct contact with one end portion of the n-electrode 21 and is electrically connected to the n-electrode 21. Similarly, the Schottky layer 23S is in direct contact with the other end portion of the n-electrode 21 and is electrically connected to the n-electrode 21. Note that it is sufficient that the Schottky layer 23S is in direct contact with at least one end portion of the n-electrode 21 and is electrically connected to the n-electrode 21.

That is, the sealing electrode wall 29 is not in conduction with the n-type semiconductor layer 12 due to Schottky contact, but is in direct contact with the n-electrode 21 and is electrically connected thereto. Therefore, a current flows uniformly through each of the plurality of n-electrodes 21 extending along the light-emitting functional portion 15M, so that light emission with high in-plane uniformity can be obtained.

In other words, as illustrated in FIGS. 3A and 1A, the sealing electrode wall 29 is erected on the peripheral edge portion of the n-type semiconductor layer 12, entirely surrounding the plurality of light-emitting functional portions 15M and the plurality of n-electrodes 21, and is formed as a closed rectangular annular sealing electrode wall that seals the internal space. Further, the sealing electrode wall 29 functions as an electrode directly connected to the n-electrode 21. In addition, by setting the pad metal layer 26S exposed on the outer periphery of the sealing electrode wall 29 and the exposed electrode portion of the n-pad electrode 28 to a negative potential, metal corrosion due to environmental gases and the generation of whiskers (metal crystal branches) can be suppressed.

Note that the shape of the sealing electrode wall 29 in a top view (that is, as viewed from a direction perpendicular to the semiconductor light-emitting element 10A) is not limited to a rectangular annular shape, but may be any shape as long as it is a closed annular sealing electrode wall. For example, the sealing electrode wall 29 may have an annular shape.

The n-pad electrode 28 of the sealing electrode wall 29 is bonded to the wiring substrate 40 and is used as an anode electrode when mounted on the wiring substrate 40. The n-pad electrode 28 (cathode electrode) is used together with the p-pad electrode 26 (anode electrode) as electrodes when bonding to and mounting on the wiring substrate 40. Therefore, it is preferable that the n-pad electrode 28 is formed to have approximately the same height as the p-pad electrode 26.

Specifically, the n-pad electrode 28 is formed as a Ti/Ni/Au electrode in which Ti, Ni, and Au are formed in that order, but is not limited thereto. Any electrode layer may be used as long as it has high adhesion and conductivity with the pad metal layer 26S and high bondability with a bonding material. For example, similarly to the p-pad electrode 26, Ti/Al/Ti-W/Au, Ti/Al/Rh/Au, or the like can be used.

### (Wiring Substrate)

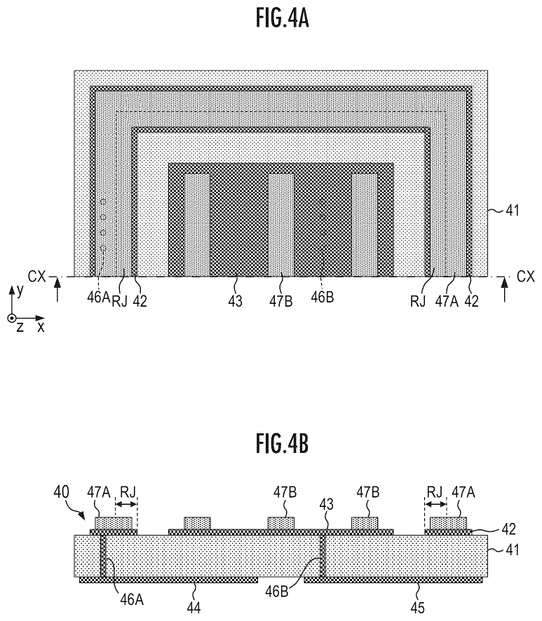

FIG. 4A is a view schematically illustrating an upper surface of the wiring substrate 40 as viewed from the bonding surface side. The wiring substrate 40 has a structure that is symmetrical with respect to the center line CX of the wiring substrate 40, and FIG. 4A illustrates the upper half of the wiring substrate 40 above the center line CX. In addition, FIG. 4B is a cross-sectional view illustrating a cross section of the wiring substrate 40 taken along the center line CX illustrated in FIG. 4A.

As illustrated in FIG. 4B, the wiring substrate (sub-mount) 40 includes a support substrate 41 made of insulating ceramic having high thermal conductivity and optical reflectivity. A first placing wiring 42 and a second placing wiring 43 are provided on the upper surface (bonding surface) of the support substrate 41, and a first mounting electrode 44 and a second mounting electrode 45 are provided on the back surface (mounting surface).

As the support substrate 41, a substrate made of aluminum nitride (AlN), silicon nitride (SiN), alumina (Al₂O₃), or the like can be used.

The first placing wiring 42 and the second placing wiring 43 are electrically connected to the first mounting electrode 44 and the second mounting electrode 45, respectively, by a first via wiring 46A and a second via wiring 46B that penetrate the support substrate 41.

As illustrated in FIG. 4A, the first placing wiring 42 is provided in an annular shape on the peripheral edge portion of the wiring substrate 40 at a position and with a size opposite to the n-pad electrode 28 of the semiconductor light-emitting element 10A. In addition, the second placing wiring 43 is provided at a position and with a size opposite to the p-pad electrode 26 of the semiconductor light-emitting element 10A.

In addition, the first via wiring 46A is provided outside a bonding region RJ to which the n-pad electrode 28 of the semiconductor light-emitting element 10A is bonded. Further, the second via wiring 46B is provided at a position opposite to the n-electrode 21.

In the present embodiment, the first mounting electrode 44 and the second mounting electrode 45 are used as an anode and a cathode, respectively, when the semiconductor light-emitting element 10A is mounted on a circuit board or the like (not illustrated).

The first placing wiring 42, the second placing wiring 43, the first mounting electrode 44, and the second mounting electrode 45 are made of a Cu/Ni/Au layer formed by stacking copper (Cu), Ni, and Au in that order. In addition, the first via wiring 46A and the second via wiring 46B are made of Cu.

A second bonding member 47B and a second bonding member 47B are placed on the first placing wiring 42 and the second placing wiring 43, respectively, and are bonded to the semiconductor light-emitting element 10A. The first placing wiring 42 functions as a sealing placing wiring that seals the semiconductor light-emitting element 10A by bonding.

More specifically, a first bonding member 47A is provided in an annular shape on the first placing wiring 42. In addition, the second bonding members 47B are provided on the second placing wiring 43 at positions corresponding to the plurality of light-emitting functional portions 15M, respectively.

For the second bonding members 47B and the first bonding members 47A, for example, a gold-tin alloy (Au-22 wt % Sn) can be used.

### (2) Manufacturing Method for Semiconductor Light-Emitting Device

A manufacturing method for the semiconductor light-emitting device 10 will be described below with reference to the drawings. FIGS. 5A to 5D are cross-sectional views illustrating steps S0 to S11 of the manufacturing method.

### (S0) Preparation of Epitaxial Wafer

An epitaxial wafer 10E having a light-emitting semiconductor multilayer structure made of aluminum gallium nitride (AlGaN) crystal formed on the element substrate 11 is prepared. Specifically, the epitaxial wafer 10E has a semiconductor multilayer structure having a light-emitting function, in which the n-type semiconductor layer 12, the light-emitting layer 13, and the p-type semiconductor layer 14 are sequentially crystal-grown. Here, for the element substrate 11, aluminum nitride (AlN) was used. In addition, the crystal growth method used was metal organic chemical vapor deposition method (MOCVD method).

In the following, unless otherwise specified, a single unit of the semiconductor light-emitting element 10A of the epitaxial wafer 10E will be described.

### (S1) Formation of Light-Emitting Region

A resist mask was formed on the epitaxial wafer 10E to cover the strip-shaped portion serving as the light-emitting region (light-emitting functional portion 15M). Next, the semiconductor layer in the opening portion of the resist mask was etched by dry etching such as a reactive ion etching (RIE) method or an inductively coupled plasma (ICP) method until the n-type semiconductor layer 12 was exposed.

Subsequently, the resist mask was removed by washing. Note that, a description of the washing and removal of the resist mask that is appropriately performed in each of the following steps will be omitted.

Through this step, grooves 12G were formed between the mesa-shaped light-emitting functional portions 15M, and stepped annular recesses 12D (step bottom portions) surrounding the plurality of light-emitting functional portions 15M were formed on the outer peripheral portion of the epitaxial wafer 10E. Note that the height of the light-emitting functional portion 15M (mesa) was HM.

(S2) Formation of n-Ohmic Electrode

Using a photolithography method, a resist mask was formed by exposing a portion where the n-ohmic electrode 21A was to be formed at the bottom portion of the groove 12G and the annular recess 12D. Subsequently, titanium (Ti, layer thickness 10 nm) and aluminum (Al, layer thickness 190 nm) were sequentially deposited by electron beam deposition (EB) method or the like.

Subsequently, a heat treatment (sintering) was performed to improve adhesion, and to form an ohmic contact. In this way, the n-ohmic electrode 21A was formed.

Note that the electrode metal is not limited to Ti/Al. For example, Ti/rhodium (Rh) or the like can be used.

(S3) Formation of p-Ohmic Electrode and Schottky Layer

A resist mask was formed along the light-emitting functional portion 15M by exposing a portion where the p-ohmic electrode 23A was to be formed on the p-type semiconductor layer 14 of the light-emitting functional portion 15M. Subsequently, nickel (Ni, layer thickness 20 nm) and gold (Au, layer thickness 180 nm) were sequentially deposited using an EB device to form a Ni/Au layer.

In addition, at the same time, outside the n-ohmic electrode 21A, a rectangular annular Ni/Au layer was formed on the bottom surface of the annular recess 12D of the n-type semiconductor layer 12, entirely surrounding the plurality of light-emitting functional portions 15M and the n-ohmic electrode 21A, and centered on a central axis CZ perpendicular to the n-type semiconductor layer 12.

Subsequently, heat treatment (sintering) was performed to improve adhesion. In addition, an ohmic contact was formed between the p-type semiconductor layer 14 of the light-emitting functional portion 15M and the p-ohmic electrode 23A.

On the other hand, the rectangular annular Ni/Au layer (Schottky layer 23S) formed on the bottom surface of the annular recess 12D of the n-type semiconductor layer 12 is formed in close contact with the n-type semiconductor layer 12, but is a Schottky layer that is in Schottky contact with the n-type semiconductor layer 12.

Note that the electrode metal is not limited to Ni/Au. For example, Ni/palladium (Pd)/Au, Ni/platinum (Pt)/Au, or the like can be used.

### (S4) Formation of Auxiliary Electrode

A resist mask was formed by exposing the n-ohmic electrode 21A, the p-ohmic electrode 23A, and the Schottky layer 23S. Subsequently, Ti, Ni, and Au were sequentially deposited by an EB method or the like.

In this way, the n-auxiliary electrode 21B was formed on the n-ohmic electrode 21A, the p-auxiliary electrode 23B was formed on the p-ohmic electrode 23A, and the auxiliary electrode 21S was formed on the Schottky layer 23S.

The n-auxiliary electrode 21B, the p-auxiliary electrode 23B, and the auxiliary electrode 21S were formed in close contact with a base layer. Further, the n-auxiliary electrode 21B, the p-auxiliary electrode 23B, and the auxiliary electrode 21S function to uniformly supply power supplied from the p-pad electrode 26, the n-pad electrode 28, and the pad metal layer 26S to each semiconductor layer.

Note that a Ti or Ni layer is provided as the final layer of the n-auxiliary electrode 21B, the p-auxiliary electrode 23B, and the auxiliary electrode 21S, the adhesion to the insulating film (SiO₂) formed thereon is improved.

### (S5) Formation of Insulating Film

SiO₂ was deposited on the entire surface using a sputtering device to form an insulating film 25 (the first insulating film 25).

### (S6) Formation of Connection Region

A resist mask was formed having openings in the p-connection region RP which is a connection region with the p-pad electrode 26 and an n-connection region RN which is a connection region with the pad metal layer 26S. Subsequently, SiO₂ in the p-connection region RP and the n-connection region RN was removed with buffered hydrofluoric acid.

Finally, washing was performed to form a p-connection region RP and an n-connection region RN.

### (S7) Formation of Pad Electrode

A resist mask was formed having openings such that the p-connection region RP and the n-connection region RN are separately included and separated from each other. Using an EB device, Ti, Ni, Au, and Ti were sequentially formed to form the p-pad electrode 26 and the pad metal layer 26S on the p-connection region RP and the n-connection region RN, respectively.

(S8) Formation of n-Pad Electrode

A resist mask having an opening on the top surface of the pad metal layer 26S was formed. Subsequently, Ti (layer thickness: 10 nm), Ni (layer thickness: 300 nm), and Au were sequentially formed using an EB device to form an n-pad electrode 28.

Through the above steps, the p-electrode 23 (second electrode) and the p-pad electrode 26 were formed on the upper surface of the light-emitting functional portion 15M, with the p-ohmic electrode 23A and the p-auxiliary electrode 23B stacked thereon, and the n-electrode 21 (first electrode) was formed on the upper surface of the separation groove 12G and the annular recess 12D, with the n-ohmic electrode 21A and the n-auxiliary electrode 21B stacked thereon. Further, the rectangular annular sealing electrode wall 29 was formed on the outer edge upper surface of the annular recess 12D by being in close contact with the Schottky layer 23S, the auxiliary electrode 21S, the pad metal layer 26S, and the n-pad electrode 28 to each other.

Note that the total thickness HM of the base layer of the n-pad electrode 28, that is, the auxiliary electrode 21S, the pad metal layer 26S, and the Schottky layer 23S, was set to be the same as the thickness (mesa height) of the light-emitting functional portion 15M. The base layer is formed in the same process as the p-ohmic electrode 23A, the p-auxiliary electrode 23B, and the p-pad electrode 26 on the light-emitting functional portion 15M, and has the same layer structure and layer thickness. Therefore, the layer thickness HE of the n-pad electrode 28 was set to be the same as HM (HE=HM), and the upper surface of the n-pad electrode 28 and the upper surface of the p-pad electrode 26 were set to be at the same height (that is, on the same plane).

In other words, the n-pad electrode 28 was formed to a layer thickness such that the height of the upper surface of the n-pad electrode 28 coincided with the height of the upper surface of the p-pad electrode 26. That is, the sealing electrode wall 29 was formed so that the height of the sealing electrode wall 29 coincided with the height of the upper surface of the p-pad electrode 26.

### (S9) Singulation

The wafer including the plurality of semiconductor light-emitting elements 10A formed as described above was singulated into individual semiconductor light-emitting elements 10A by laser dicing DC.

### (S10) Bonding Between Semiconductor Light-Emitting Element and Wiring Substrate

The wiring substrate (sub-mount) 40 had an aluminum nitride (AlN) ceramic substrate as a support substrate 41, and a first placing wiring 42 and a second placing wiring 43 made of Cu/Ni/Au layers were provided on the front surface of the support substrate 41, and a second mounting electrode 45 and a first mounting electrode 44 made of Cu/Ni/Au layers were provided on the back surface. In addition, a first via wiring 46A and a second via wiring 46B were provided to electrically connect the first placing wiring 42 and the second placing wiring 43 to the first mounting electrode 44 and the second mounting electrode 45, respectively.

First, the first bonding member 47A and the second bonding member 47B were disposed on the first placing wiring 42 and the second placing wiring 43, respectively. Specifically, a gold-tin alloy (Au-22 wt % Sn) was deposited as the second bonding member 47B and the first bonding member 47A using a photolithography method and by EB or resistance heating. Note that the first bonding member 47A was deposited in an annular shape corresponding to the first placing wiring 42.

Next, under reduced pressure and a nitrogen atmosphere, the n-pad electrode 28 (sealing electrode wall 29) and p-pad electrode 26 of the semiconductor light-emitting element 10A were aligned with the first bonding member 47A and the second bonding member 47B, and the first placing wiring 42 and the second placing wiring 43, and were pressed against each other while being heated to 300° C. to melt and solidify the bonding members, thereby bonding the semiconductor light-emitting element 10A to the wiring substrate 40.

Note that as illustrated in FIG. 5D, the excess portion of the second bonding member 47B when melted flows into the valleys between the light-emitting functional portions 15M, thereby preventing a short circuit between the electrodes. In addition, the first placing wiring 42 has an extra width portion WO that extends in the outer circumferential direction beyond a width WM of the n-pad electrode 28, and when melted, the excess portion of the first bonding member 47A spreads over the extra width portion WO, thereby preventing a short circuit between the electrodes.

Through the above steps, the semiconductor light-emitting device 10 illustrated in FIG. 2 was manufactured.

In the semiconductor light-emitting device 10, the annular sealing electrode wall 29 having airtightness is airtightly bonded to the first placing wiring 42 of the wiring substrate 40 by the first bonding member 47A. That is, the semiconductor light-emitting element 10A and the wiring substrate 40 are airtightly bonded continuously over the entire periphery by the first bonding member 47A, and the inside of the sealing electrode wall 29 forms an airtight space AS. Therefore, the semiconductor light-emitting device 10 having high resistance to external environmental factors such as external gases and humidity can be obtained.

In particular, when the semiconductor light-emitting element 10A is driven, the n-type semiconductor layer 12 and the element substrate 11, and the bonded portion including the bonding member 47 and the sealing electrode wall 29 are brought to a negative potential. Therefore, in the semiconductor light-emitting device 10, even in a case where the n-type semiconductor layer 12 and the element substrate 11 are exposed to the external environment, reaction with corrosive atmospheric gases such as oxygen, water vapor, nitrogen oxides, and sulfur oxides is prevented, and high corrosion resistance and moisture resistance are obtained.

Further, the p-type semiconductor layer 14 of the semiconductor light-emitting element 10A, which is susceptible to corrosion (deterioration) due to a corrosive atmospheric gas, is provided with high corrosion resistance and moisture resistance by the double sealing provided by the sealing electrode wall 29 in addition to the first insulating film 25.

As described above in detail, the semiconductor light-emitting device 10 according to the present embodiment is provided with the annular sealing electrode wall 29 that entirely surrounds at least one light-emitting functional portion 15M and the n-electrode 21 and has airtightness. The annular sealing electrode wall 29 is airtightly bonded to the first placing wiring 42 of the wiring substrate 40 having an annular shape corresponding to the sealing electrode wall 29, and the inside of the sealing electrode wall 29 forms the airtight space AS. Therefore, the semiconductor light-emitting device 10 having high resistance to the external environment can be obtained.

### (3) Moisture Resistance Test

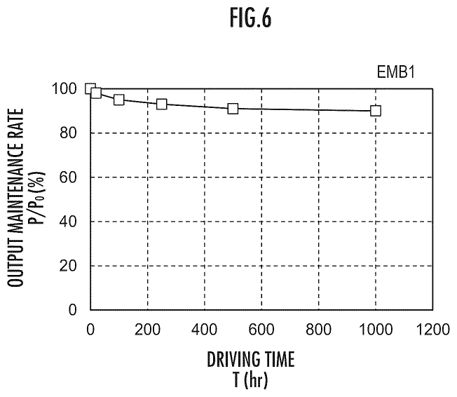

A moisture resistance test was carried out on the semiconductor light-emitting device 10 according to the first embodiment and the semiconductor light-emitting device according to the comparative example manufactured as described above. FIG. 6 is a graph showing results of a moisture resistance test of the semiconductor light-emitting device 10 according to Example 1 (EMB1).

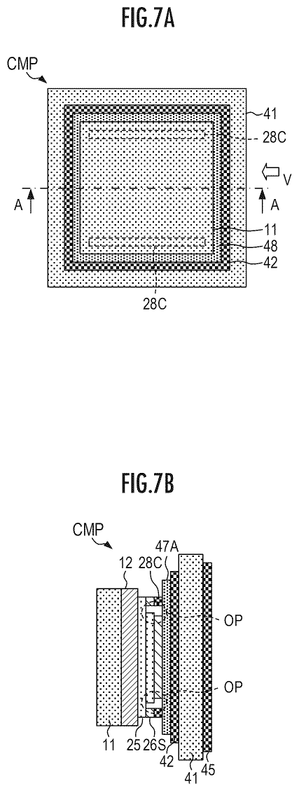

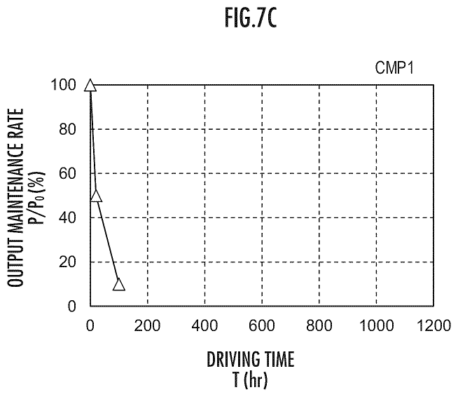

In addition, FIG. 7A is a top view schematically illustrating a semiconductor light-emitting device according to Comparative Example 1 (CMP1) as viewed from above (the light-emitting surface side). FIG. 7B is a view schematically illustrating a side surface of the semiconductor light-emitting device according to Comparative Example 1 as viewed from a direction V illustrated in FIG. 7A. In addition, FIG. 7C is a graph showing results of a moisture resistance test of the semiconductor light-emitting device according to Comparative Example 1.

As illustrated in FIGS. 7A and 7B, the semiconductor light-emitting device according to Comparative Example 1 differs from the semiconductor light-emitting device 10 according to Example 1 in that only a pair of n-pad electrodes (first pad electrodes) 28C are provided along two opposing sides of the semiconductor light-emitting device and are bonded to a first placing wiring 42 on a support substrate 41. Other points are similar to those of the semiconductor light-emitting device 10. That is, the semiconductor light-emitting device according to Comparative Example 1 has an opening OP in a region other than the bonding region of the n-pad electrode 28C, and is exposed to the external environment through the opening OP.

The moisture resistance test was performed in an environment of a temperature of 60° C. and a humidity of 90% by applying a constant current of 440 mA. The initial output P0 (driving time T=0 hr) was P0=56 mW for both the semiconductor light-emitting device 10 according to Example 1 and the semiconductor light-emitting device according to Comparative Example 1.

As illustrated in FIG. 6, in the semiconductor light-emitting device 10 according to Example 1, the light output maintenance rate (%) was 91% even after the driving time T had elapsed 1000 hours, and was maintained at 90% or more. Note that the light output maintenance rate (%) was calculated as the ratio P/P0 (%) of the light output P after a predetermined time had elapsed to the initial output P0.

On the other hand, in the semiconductor light-emitting device according to Comparative Example 1, as illustrated in FIG. 7C, P/P0 was 50% when the driving time T was 20 hrs, and P/P0 was 10% when the driving time T was 100 hrs, which was a large deterioration.

That is, the deterioration of the life of the semiconductor light-emitting device 10 according to Example 1 was the same as that of the sealed structure in which the semiconductor light-emitting element was sealed with a glass cap, and was due to aging and deterioration due to electrical current. It was confirmed that the semiconductor light-emitting device 10 according to the present embodiment has high environmental resistance.

### (4) Modification Example 1

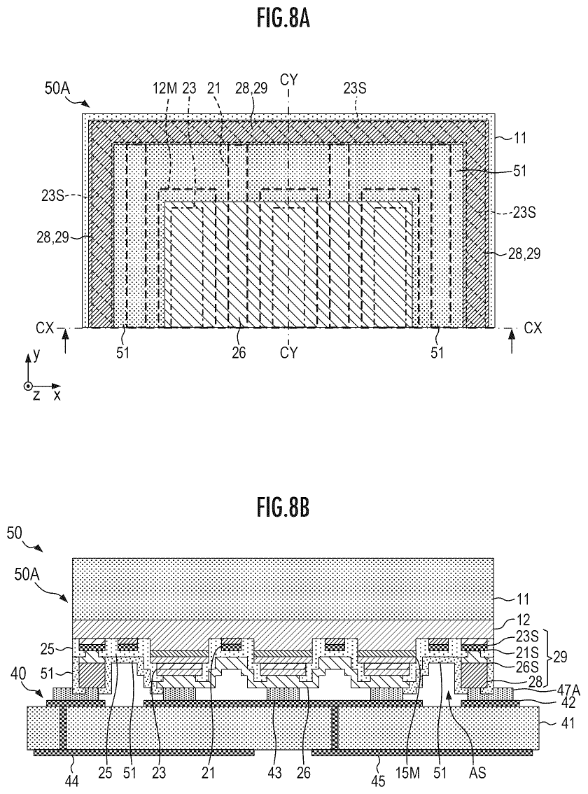

FIG. 8A is a view schematically illustrating an element upper surface of a semiconductor light-emitting element 50A according to Modification Example 1 of the first embodiment described above. The semiconductor light-emitting element 50A has a rectangular structure that is symmetrical with respect to the center line CX, and FIG. 8A illustrates the upper half of the semiconductor light-emitting element 50A above the center line CX.

In addition, FIG. 8B is a cross-sectional view illustrating a cross section taken along a center line CX of a semiconductor light-emitting device 50 according to Modification Example 1 formed by bonding the semiconductor light-emitting element 50A according to Modification Example 1 to the wiring substrate 40.

In the semiconductor light-emitting element 50A according to Modification

Example 1, a second insulating film 51 is provided to cover the first insulating film 25 and to cover a region between the annular sealing electrode wall 29 and the p-pad electrode 26. The second insulating film 51 is made of, for example, SiO₂. An insulating film such as SiO₂ repels the molten AuSn bonding member. Therefore, it is possible to prevent short circuits from occurring between the electrodes during the bonding step. Further, since the SiO₂ film blocks gas, the weather resistance of the semiconductor light-emitting device can be further improved.

The second insulating film 51 can be formed by adding the following steps S8-2 and S8-3 after the n-pad electrode formation step (S8) described above. FIG. 9 is a cross-sectional view illustrating steps S8-2 and S8-3.

That is, in step S8-2 (formation of SiO₂ film), a SiO₂ film is formed on the entire surface of the element by a sputtering device. The film thickness can be set to 400 nm, for example.

Next, in step S8-3 (formation of openings for exposing electrode pads), openings are formed in the SiO₂ film, exposing the p-pad electrode 26 and the n-pad electrode 28.

According to Modification Example 1, a semiconductor light-emitting device with even better environmental resistance can be provided.

### (5) Modification Example 2

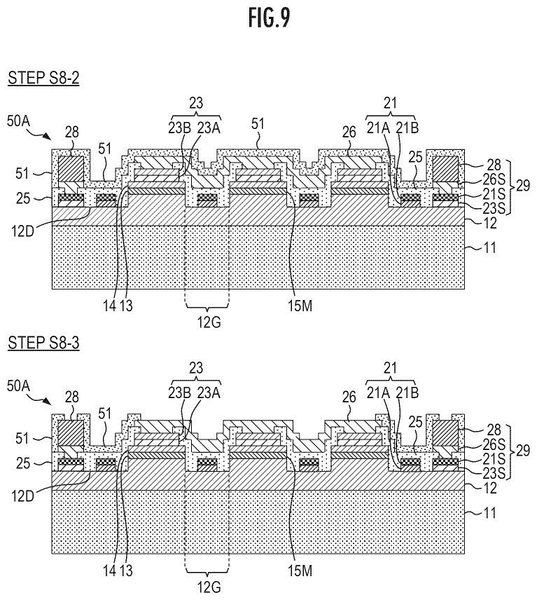

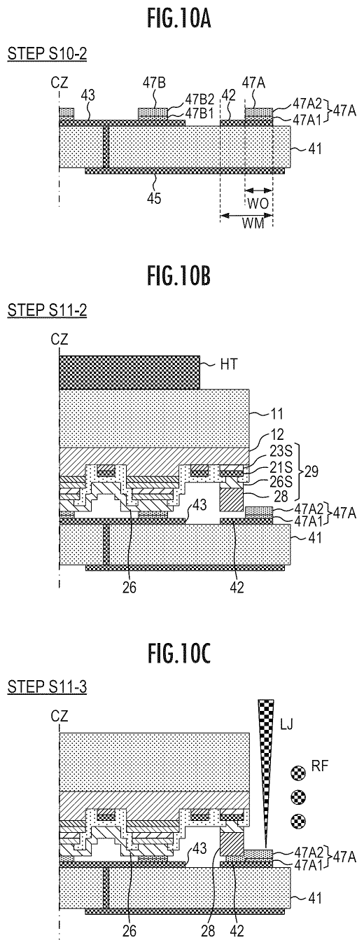

FIGS. 10A to 10C are cross-sectional views illustrating a modification example (Modification Example 2) of the manufacturing method according to the first embodiment described above. Note that FIGS. 10A to 10C illustrate the right half with respect to a central axis CZ perpendicular to the n-type semiconductor layer 12.

Instead of the above-described step of bonding the semiconductor light-emitting element and the wiring substrate (S10), a two-stage bonding step is performed. First, as illustrated in FIG. 10A, in a bonding preparation step (S10-2), the first placing wiring 42 has an extra width portion WO that extends in the outer circumferential direction beyond the width WM of the n-pad electrode 28. Moreover, the first bonding member 47A is disposed within the extra width portion WO.

In addition, as the first bonding member 47A, a barrier metal layer 47A1 and a gold-tin (Au-22 wt % Sn) bonding material 47A2 are stacked in that order. The second bonding member 47B is also formed at the same time, and a barrier metal layer 47B1 and a gold-tin (Au-22 wt % Sn) bonding material 47B2 are stacked in that order.

As a barrier metal, in addition to platinum (Pt), metals such as titanium-tungsten (TiW) can be used. Also, instead of the barrier metal, gold-tin (Au-26 wt % Sn) can be used for the barrier metal layer 47A1 of the first bonding member 47A, and gold-tin (Au-20 wt % Sn) can be used for the barrier metal layer 47B1 of the second bonding member 47B.

Next, as illustrated in FIG. 10B, in a pad electrode bonding step (S11-2), the p-pad electrode 26 of the semiconductor light-emitting element 10A and the second bonding member 47B formed on the second placing wiring 43 of the wiring substrate 40 are aligned and pressed against each other under reduced pressure, preheated to 280° C., and nitrogen atmosphere.

Next, a heating tool HT is pulse-heated up to 330° C. to melt and solidify the second bonding member 47B, thereby bonding the semiconductor light-emitting element 10A to the wiring substrate 40. At this time, the excess portion of the second bonding member 47B flows into the valleys between the light-emitting functional portions 15M, thereby preventing a short circuit between the electrodes. In addition, the first bonding member 47A does not reach its melting temperature and is therefore not bonded.

At this time, by inserting the barrier metal layer 47A1, it is possible to prevent the gold-tin bonding material 47A2 of the first bonding member 47A from being unintentionally melted, due to the absorption of the uppermost Au layer of the first placing wiring 42 and the second placing wiring 43 (Cu/Ni/Au layer) into the gold-tin bonding material.

Subsequently, in a sealing electrode wall bonding step (S11-3), the semiconductor light-emitting device in which the p-pad electrode 26 of the semiconductor light-emitting element 10A and the second placing wiring 43 of the wiring substrate 40 are bonded is set in a laser bonding apparatus LJ or an RF heating apparatus RF as illustrated in FIG. 10C, and preheated to 280° C. under reduced pressure and a nitrogen atmosphere.

Next, the first bonding member 47A is heated (for example, to 330° C.) by laser light heating or RF heating until the first bonding member 47A melts, and the molten first bonding member 47A is caused to flow between the first placing wiring 42 and the n-pad electrode (first pad electrode) 28 to bond the semiconductor light-emitting element 10A to the wiring substrate 40. Accordingly, the first placing wiring 42 and the sealing electrode wall 29 are bonded to each other.

At this time, the first bonding member 47A flows into the gap due to capillary action, and therefore bonding can be performed without spreading inside. Further, since the heating is localized, the second bonding member 47B that has already been bonded does not melt.

Since a barrier metal layer is provided on the first placing wiring 42 and the second placing wiring 43, it is possible to prevent a decrease in bondability and airtightness due to the absorption of the uppermost Au layer of the first placing wiring 42 and the second placing wiring 43 (Cu/Ni/Au layer) into the gold-tin bonding material when the gold-tin bonding materials 47A2 and 47B2 are heated.

### Second Embodiment

A semiconductor light-emitting device 60 including a semiconductor light-emitting element 60A according to a second embodiment of the present invention will be described below with reference to the drawings.

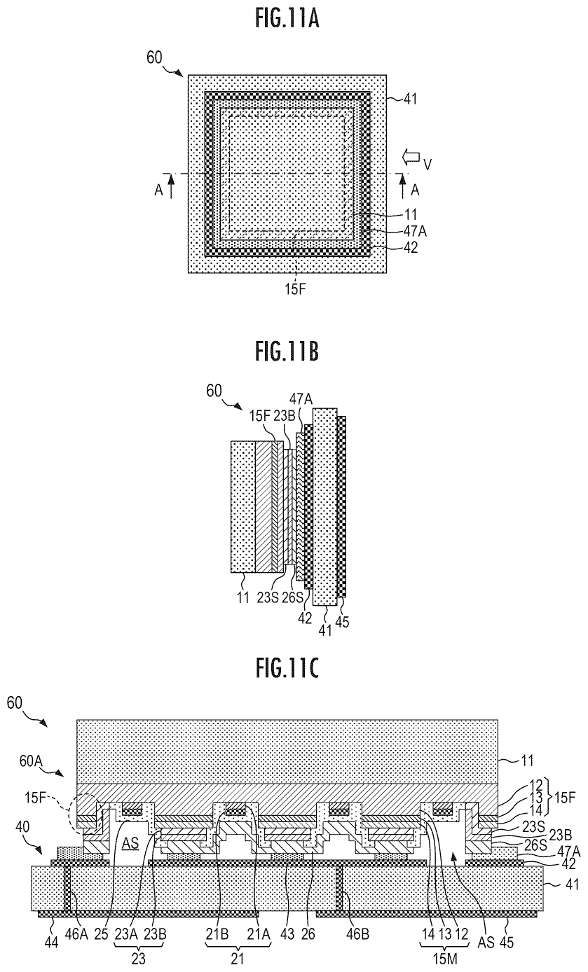

FIG. 11A is a top view schematically illustrating the semiconductor light-emitting device 60 according to the second embodiment as viewed from above (the light-emitting surface side). FIG. 11B is a view schematically illustrating a side surface of the semiconductor light-emitting device 60 as viewed from a direction V illustrated in FIG. 11A. In addition, FIG. 11C is a cross-sectional view schematically illustrating a cross section taken along line A-A illustrated in FIG. 11A.

As illustrated in FIGS. 11A to 11C, the semiconductor light-emitting device 60 includes a rectangular plate-shaped wiring substrate 40 and a semiconductor light-emitting element 60A bonded to the wiring substrate 40. Similarly to the semiconductor light-emitting device 10 according to the first embodiment, the semiconductor light-emitting element 60A has a rectangular plate shape, and is provided with a plurality of semiconductor light-emitting functional portions 15M on the bonding surface side with the wiring substrate 40.

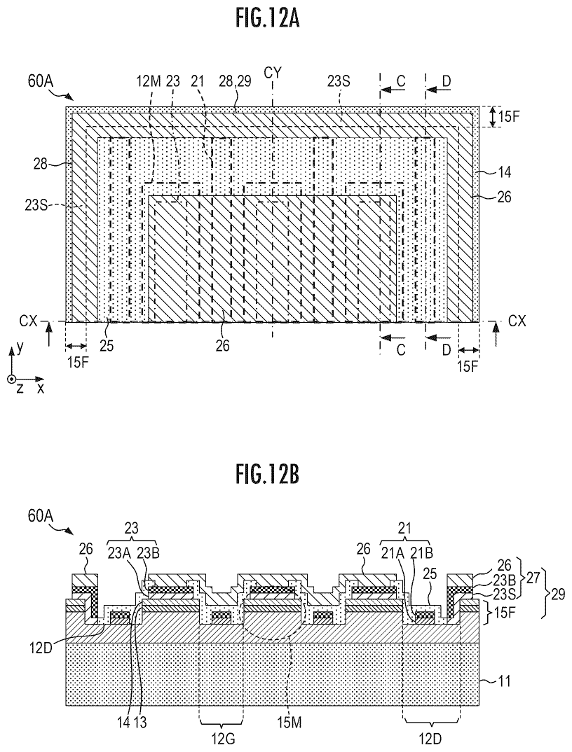

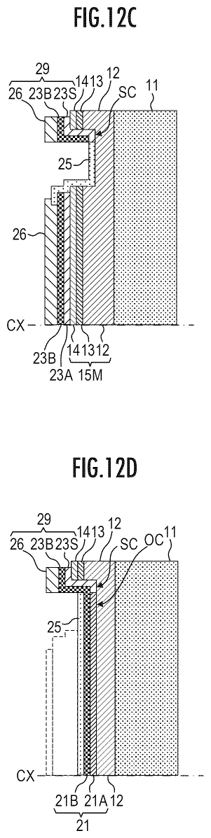

In the semiconductor light-emitting device 60 according to the second embodiment, the semiconductor light-emitting element 60A differs from the semiconductor light-emitting element 10A according to the first embodiment in that the semiconductor light-emitting element 60A includes a rectangular annular frame portion 15F at its peripheral end portion that protrudes toward the bonding surface with the wiring substrate 40. Note that the wiring substrate 40 of the present embodiment is the same as the wiring substrate 40 of the first embodiment. This will be described in more detail below with reference to FIGS. 12A to 12D.

FIG. 12A is a view schematically illustrating an element upper surface of the semiconductor light-emitting element 60A as viewed from the bonding surface side of the semiconductor light-emitting element 60A and the wiring substrate 40. Note that FIG. 12A illustrates the semiconductor light-emitting element 60A in FIG. 11C upside down. Also, the semiconductor light-emitting element 60A has a rectangular structure that is symmetrical with respect to a center line CX, and FIG. 12A illustrates the upper half of the semiconductor light-emitting element 60A above the center line CX.

In addition, FIG. 12B is a cross-sectional view illustrating a cross section of the semiconductor light-emitting element 60A taken along the center line CX. FIGS. 12C and 12D are cross-sectional views illustrating cross sections taken along lines C-C and D-D illustrated in FIG. 12A, respectively.

As illustrated in FIGS. 12A and 12B, an annular recess 12D is provided at the peripheral edge portion of the n-type semiconductor layer 12. In the present embodiment, the annular recess 12D is formed as a rectangular annular groove, and a rectangular annular frame portion 15F is formed on the outer periphery side of the annular recess 12D.

The annular recess 12D has the same depth as the separation groove 12G, and therefore the frame portion 15F has the same height as the semiconductor light-emitting functional portion 15M. Further, a sealing electrode layer 27 consisting of a Schottky layer 23S, a p-auxiliary electrode 23B, and a p-pad electrode 26 is formed so as to extend from the bottom surface of the annular recess 12D to cover the side surface of the frame portion 15F and to ride up onto the frame portion 15F to cover at least a portion of the upper surface of the frame portion 15F.

The sealing electrode layer 27 has a rectangular annular shape corresponding to the frame portion 15F, and is formed in close contact with the bottom surface of the annular recess 12D and the frame portion 15F. Further, in the sealing electrode layer 27, the Schottky layer 23S is in Schottky contact with the n-type semiconductor layer 12, and thus no electrical current flows between the sealing electrode layer 27 and the n-type semiconductor layer 12.

The frame portion 15F and the sealing electrode layer 27 entirely surround the plurality of light-emitting functional portions 15M and the n-electrode 21, and function as an annular sealing electrode wall 29 having airtightness. Since the thickness of the sealing electrode layer 27 is the same as the total thickness of the p-electrode 23 and the p-pad electrode 26, which are the electrode layers on the p-type semiconductor layer 14, the sealing electrode layer 27 has the same height as the p-pad electrode 26 on the semiconductor light-emitting functional portion 15M.

That is, the upper surface of the sealing electrode layer 27 and the upper surface of the p-pad electrode 26 on the semiconductor light-emitting functional portion 15M are on the same plane. Therefore, the semiconductor light-emitting element 60A can be easily bonded in parallel to the wiring substrate 40, and the bonding stability is high, and the bonding adhesion and sealing properties are excellent.

In the semiconductor light-emitting device 60, the annular sealing electrode wall 29 having airtightness is airtightly bonded to the first placing wiring 42 of the wiring substrate 40 by the first bonding member 47A. That is, the semiconductor light-emitting element 10A and the wiring substrate 40 are airtightly bonded continuously over the entire periphery by the first bonding member 47A, and the inside of the sealing electrode wall 29 forms an airtight space AS. Therefore, the semiconductor light-emitting device 10 having high resistance to external environmental factors such as external gases and humidity can be obtained.

In addition, as illustrated in FIGS. 12C and 12A, in the region where the n-electrode 21 is not formed, the Schottky layer 23S (that is, the sealing electrode wall 29) is not electrically connected (non-conductive) to the n-electrode 21.

On the other hand, as illustrated in FIGS. 12D and 12A, in the region where the n-electrode 21 is formed, the Schottky layer 23S (that is, the sealing electrode wall 29) is in direct contact with and electrically connected to the n-electrode 21 at both end portions of the n-electrode 21. Further, the p-type semiconductor layer 14 of the frame portion 15F is not brought to a positive potential even when an electrical current flows, and is therefore not corroded.

Therefore, a current flows uniformly through each of the plurality of n-electrodes 21 extending along the light-emitting functional portion 15M, so that light emission with high in-plane uniformity can be obtained.

### Third Embodiment

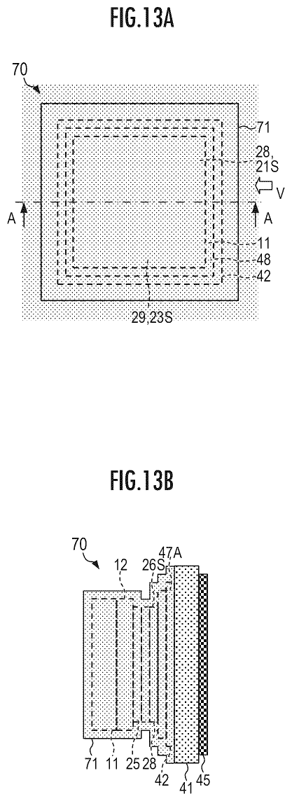

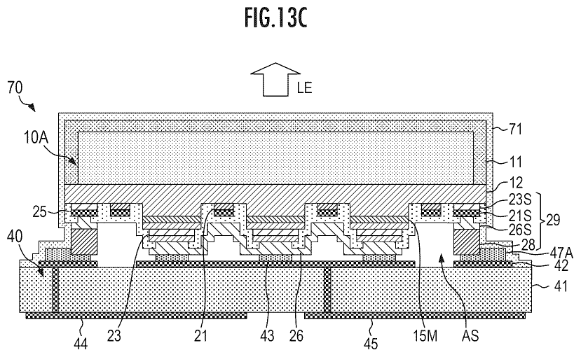

A semiconductor light-emitting device 70 according to a third embodiment of the present invention will be described below with reference to the drawings. FIG. 13A is a top view schematically illustrating the semiconductor light-emitting device 70 as viewed from above (top view). FIG. 13B is a view schematically illustrating a side surface of the semiconductor light-emitting device 70 as viewed from a direction V illustrated in FIG. 13A. In addition, FIG. 13C is a cross-sectional view schematically illustrating a cross section taken along line A-A illustrated in FIG. 13A.

The semiconductor light-emitting device 70 includes a protective film 71 that covers the semiconductor light-emitting element 10A of the semiconductor light-emitting device 10 according to the first embodiment described above. More specifically, the semiconductor light-emitting device 70 includes a wiring substrate 40 and a semiconductor light-emitting element 10A bonded to the wiring substrate 40.

The protective film 71 is formed from the upper surface of the wiring substrate 40 to the semiconductor light-emitting element 10A. That is, the protective film 71 entirely covers a first placing wiring 42 (sealing portion wiring) of the wiring substrate 40, a first bonding member 47A (sealing bonding member), and an exposed outer surface which is the exposed surface of the semiconductor light-emitting element 10A.

In the semiconductor light-emitting device 70, similarly to the semiconductor light-emitting devices 10 and 60 according to the first and second embodiments, the semiconductor light-emitting element 10A and the wiring substrate 40 are airtightly bonded continuously over the entire periphery by the first bonding member 47A. Therefore, the protective film 71 can cover the outer surface of the device without interruption.

With the semiconductor light-emitting device 70 according to the present embodiment, it is possible to provide a semiconductor light-emitting device that has further high resistance to the external environment.

### (Type of Protective Film)

As the protective film 71, a single-layer or multi-layer protective film, a dielectric multilayer film for controlling the directional characteristics, an antireflection film for improving the light extraction efficiency, or the like can be employed. The details will be described below.

### (1) Fluororesin Film (Organic Protective Film):

The fluororesin film can be formed by resistance heating deposition, electron beam (EB) deposition, or sputtering. By using such a physical vapor deposition method, the preheating temperature of the semiconductor light-emitting device 70 can be set to 100° C. to 300° C. Therefore, the fluororesin film can be formed without damaging the bonded portion. Also, the occurrence of pinholes is suppressed. Note that, as the fluororesin, tetrafluoroethylene-perfluoro (alkoxyvinyl ether) copolymer (PFA), tetrafluoroethylene-hexafluoropropylene copolymer (FEP), ethylene tetrafluoroethylene (ETFE), polyvinylidene fluoride (PVDF), polytetrafluoroethylene (PTFE), or the like can be selected. The fluororesin is most suitable as a protective film because it is inactive to chemical substances and has extremely low gas permeability.

### (2) Dielectric Film (Inorganic Protective Film):

The dielectric film can be formed by EB deposition or an atomic layer deposition (ALD) method. Particularly, the ALD method is preferable because it can reliably form a film even on finely uneven portions. By using these physical vapor deposition methods, the preheating temperature of the light-emitting device can be set to 100° C. to 300° C., and thus the dielectric film can be formed without damaging the bonded portion. Also, the occurrence of pinholes is suppressed. As the dielectric film, silicon oxide (SiO₂), alumina (Al₂O₃), zirconia (ZrO₂), titanium oxide (TiO₂), or the like can be selected. Films of inorganic substances are preferred because the films have no gas permeability.

### (3) Dielectric Multilayer Film (Control of Directional Characteristics):

The dielectric multilayer film can be formed by the above-described dielectric film forming method. For example, in a case where a dielectric multilayer film is used that has a transmittance of about 50% when light emitted from a light-emitting element is perpendicularly incident, the directional characteristics can be flattened (wide light distribution). Note that such a film can be obtained by stacking several pairs to several tens of pairs of two or more films with different refractive indices, such as silicon oxide (SiO₂), alumina (Al₂O₃), zirconia (ZrO₂), and titanium oxide (TiO₂).

### (4) Antireflection Film (Improvement of Light Output):

The antireflection film can be formed by the above-described dielectric film forming method. For example, the layer configuration is formed so that the light emitted from the light-emitting element is not reflected. For example, such a film can be obtained by stacking substances with different refractive indices, such as silicon oxide (SiO₂), alumina (Al₂O₃), zirconia (ZrO₂), and titanium oxide (TiO₂), in a film thickness that reduces the reflected light.

### Fourth Embodiment

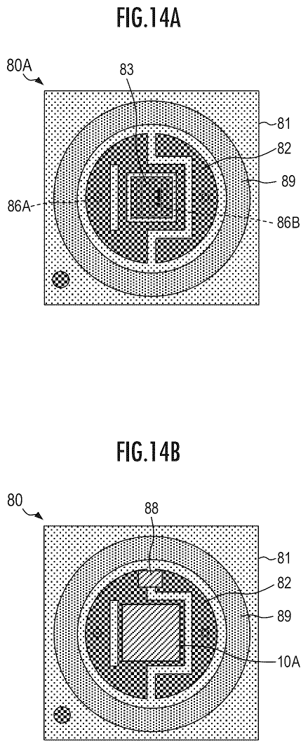

A semiconductor light-emitting device 80 according to a fourth embodiment of the present invention will be described below with reference to the drawings. FIG. 14A is a top view schematically illustrating a bonding surface (element mounting surface) of a wiring substrate 80A of the semiconductor light-emitting device 80. FIG. 14B is a top view schematically illustrating the semiconductor light-emitting device 80 in which a semiconductor light-emitting element 10A is mounted on the wiring substrate 80A.

As illustrated in FIG. 14A, the wiring substrate 80A includes a support substrate 81, a first placing wiring 82 (cathode) and a second placing wiring 83 (anode), and a first via wiring 86A and a second via wiring 86B.

As illustrated in FIG. 14B, the semiconductor light-emitting element 10A and a protective element 88 are bonded to the first placing wiring 82 and the second placing wiring 83 and mounted.

The semiconductor light-emitting element 10A has an annular sealing electrode wall 29 bonded to the first placing wiring 82 by a bonding member, and is sealed in an airtight manner on the wiring substrate 80A. That is, since an airtight structure as the light-emitting device is formed by bonding the light-emitting element and the wiring substrate, there is no restriction on the size of the wiring substrate, and the wiring substrate can be made large.

By increasing the size of the wiring substrate, the highly thermally conductive ceramic serving as the support substrate 81 can improve the dissipation of heat generated during driving. By improving the heat dissipation, the temperatures of the light-emitting element and the bonding members are reduced, and thus the corrosion resistance is improved.

Further, by increasing the size of the wiring substrate, it is possible to ensure space for placing other elements on the support substrate 81, and it is also possible to route wiring. Therefore, it is possible to mount a protective element and a driving element.

As the protective element 88, a Zener diode (ZD), a varistor, a chip capacitor, or the like that protects the semiconductor light-emitting element 10A from electrostatic breakdown can be used. Further, a system IC or the like can be used as a driving element for controlling the lighting and output of the semiconductor light-emitting element 10A.

### Fifth Embodiment

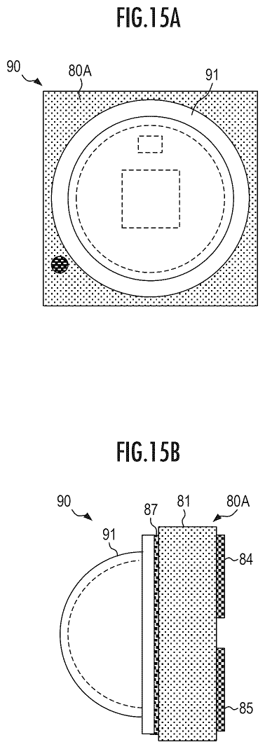

FIGS. 15A and 15B are a top view and a side view, respectively, of a semiconductor light-emitting device 90 according to a fifth embodiment of the present invention.

As illustrated in FIGS. 15A and 15B, a substrate frame edge metal layer 89 is provided to surround the mounting region of a semiconductor light-emitting element 10A and a protective element 88, separated from the mounting region, thereby forming a cap-sealed semiconductor light-emitting device 90.

The semiconductor light-emitting device 90 includes a semispherical dome-shaped light-transmitting cap (glass cap) 91 bonded to the substrate frame edge metal layer 89 by a bonding member 87.

In addition, a first mounting electrode 84 (cathode) and a second mounting electrode 85 (anode) are provided on the back surface of a support substrate 81 of a wiring substrate 80A, which are connected to a first placing wiring 82 and a second placing wiring 83 via a first via wiring 86A and a second via wiring 86B, respectively, and the semiconductor light-emitting element 10A can be driven when an electrical current flows.

The semiconductor light-emitting device 90 has a double sealed structure in which the semiconductor light-emitting element 10A and the protective element 88 are sealed with a light-transmitting cap 91. Therefore, the semiconductor light-emitting device 90 can ensure high reliability even in harsher environments of high temperature, high humidity, and corrosive gas.

Although the embodiments of the present invention have been described in detail above, the configurations, crystal systems, materials, and the like of the semiconductor layers described above are merely examples. The present invention can be applied with appropriate modifications without departing from the scope of the present invention.

As described above, the present invention can provide a semiconductor light-emitting element and a semiconductor light-emitting device that are highly reliable even in harsh environments such as high temperature, high humidity, and corrosive gas environments.

### DESCRIPTION OF REFERENCE NUMERALS

10, 50, 60, 70, 80, 90: semiconductor light-emitting device
10A, 50A, 60A, 80A: semiconductor light-emitting element
11: element substrate
12: first semiconductor layer (n-type semiconductor layer)
12D: annular recess
12G: separation groove
12L: light-emitting functional semiconductor layer
13: light-emitting layer
14: second semiconductor layer (p-type semiconductor layer)
15F: frame portion
15M: light-emitting functional portion
21: n-electrode
23: p-electrode
23S: Schottky layer
25: first insulating film
26: p-pad electrode
28: n-pad electrode
29: sealing electrode wall
42: first placing wiring
43: second placing wiring
47A, 47B: bonding member
51: second insulating film
71: protective film
91: light-transmitting cap
AS: airtight space

1. A semiconductor light-emitting element comprising:
a light-transmitting element substrate;
a light-emitting functional semiconductor layer that is provided on the element substrate and includes at least one light-emitting functional portion, each of which consists of a stacked semiconductor layer in which a first semiconductor layer, a light-emitting layer, and a second semiconductor layer are sequentially stacked, and which is separated by a separation groove having a bottom surface where the first semiconductor layer is exposed;
at least one first electrode provided on the bottom surface of the separation groove;
a second electrode provided on the second semiconductor layer of the light-emitting functional portion;
a first insulating film that covers the at least one light-emitting functional portion, the separation groove, the first electrode, and the second electrode, and has an opening where a portion of the second electrode is exposed;
a connection pad electrode that is electrically connected to the second electrode through the opening and entirely covers the at least one light-emitting functional portion and the separation groove;
an annular recess that entirely surrounds the at least one light-emitting functional portion and the at least one first electrode and has a bottom surface where the first semiconductor layer is exposed; and
an annular sealing electrode wall that is in non-conductive contact with the first semiconductor layer exposed from the bottom surface of the annular recess and is erected in an annular shape on the exposed first semiconductor layer, and that entirely surrounds the at least one light-emitting functional portion and the first electrode, wherein
the annular sealing electrode wall is in direct contact with one end of the first electrode and electrically connected to the first electrode.

2. The semiconductor light-emitting element according to claim 1, further comprising an annular frame portion which is the stacked semiconductor layer on an outer periphery of the annular recess, wherein
the annular sealing electrode wall includes an annular frame portion electrode layer which rides up from the bottom surface of the annular recess onto the frame portion and covers an upper surface of the frame portion, and
the frame portion electrode layer has a same layer thickness on the upper surface of the frame portion as the second electrode and the connection pad electrode on the light-emitting functional portion.

3. The semiconductor light-emitting element according to claim 1, wherein
the annular sealing electrode wall is composed of a sealing electrode layer which is made of the same layer and has a same layer thickness as the second electrode and the connection pad electrode on the light-emitting functional portion, and a sealing pad electrode provided on the sealing electrode layer.

4. The semiconductor light-emitting element according to claim 1, further comprising a second insulating film that covers the first insulating film and is provided in a region between the annular sealing electrode wall and the connection pad electrode.

5. The semiconductor light-emitting element according to claim 1, wherein
upper surfaces of the connection pad electrode and the sealing electrode wall are on a same plane.

6. The semiconductor light-emitting element according to claim 1, further comprising a plurality of the light-emitting functional portions having a mesa shape extending in a predetermined direction and a plurality of the first electrodes extending along the plurality of light-emitting functional portions, wherein
the annular sealing electrode wall is in direct contact with and electrically connected to one end of each of the plurality of first electrodes.

7. A semiconductor light-emitting device comprising:
the semiconductor light-emitting element according to claim 1; and
a wiring substrate including a sealing placing wiring having an annular shape corresponding to the sealing electrode wall of the semiconductor light-emitting element, the sealing electrode wall and the sealing placing wiring being airtightly bonded by a bonding member.

8. The semiconductor light-emitting device according to claim 7, wherein
the bonding member is composed of a barrier metal layer provided on the sealing placing wiring and a bonding material provided on the barrier metal layer.

9. The semiconductor light-emitting device according to claim 7, wherein
the sealing placing wiring has an extra width portion that extends in an outer circumferential direction beyond a width of the sealing electrode wall.

10. The semiconductor light-emitting device according to claim 7, further comprising a protective film that covers an outer surface of the semiconductor light-emitting element from an upper surface of the wiring substrate.

11. The semiconductor light-emitting device according to claim 10, wherein
the protective film includes at least one of an organic protective film, an inorganic protective film, a dielectric multilayer film, and an antireflection film.
